(19) United States
(12) Patent Application Publication
(10) Pub. No.: US 2011/0003240 A1
(43) Pub. Date: Jan. 6, 2011

(54) Method for forming holograms

(75) Inventors: Jiro Yoshinari, Tokyo (JP); Motohiro Inoue, Tokyo (JP); Atsuko Kosuda, Tokyo (JP); Naoki Hayashida, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/801,175

(22) Filed: May 26, 2010

(30) Foreign Application Priority Data
Jul. 2, 2009 (JP) 2009-158119

(51) Int. Cl. G03F 7/00

(52) U.S. Cl. 430/2

(57) ABSTRACT

A reflection type hologram recording optical system is provided which implements a method for forming a light reflection hologram having uniform reflectivity. The method includes: focusing a first laser beam through one of a pair of objective lenses, the first beam satisfying the condition given by, 4λn/(NA)²<D, where λ (μm) is the wavelength of the first laser beam, NA is the numerical aperture of the pair of objective lenses, n is the average refractive index of the optical recording medium, and D (μm) is the thickness of the medium; allowing the first laser beam to interfere with a second laser beam within the optical recording medium, the second laser beam being focused through the other opposing objective lens; and allowing the optical recording medium and a flux of the laser beams to be displaced relative to each other, thereby forming a light reflection hologram having uniform reflectivity.

### BACKGROUND OF THE INVENTION

1. Field of the Invention

The present invention relates to a method for forming reflection holograms on an information recording layer of an optical recording medium.

2. Description of the Related Art

A device or a holographic recording medium for writing holograms thereon is disclosed in Japanese Translation of PCT Patent Application No. 2002-502057. The medium has a reflection format hologram formed therein and data written as localized alteration within the format hologram.

The recording medium disclosed in Japanese Translation of PCT. Patent Application No. 2002-502057 describes that the reflection format hologram extending across the entire volume of the recording medium is formed by two opposing plane waves which are perpendicular to the direction of depth of the recording medium and have a substantially flat peripheral portion. However, the publication made no description to the magnitude and shape of the plane waves.

In R. R. McLeod, et. al., Applied Optics, Vol. 47, No. 14, 2696 (2008), there is a description regarding an example of a servo writer for forming format holograms using mutual interference of opposing macroscopic plane waves.

Using a focused laser beam to detect a reflected beam from a reflection hologram, which had been formed through a mutual interference of macroscopic plane waves, showed that there was a significant variation in the reflected beam depending on the point of detection.

Furthermore, some optical recording media may have an undulation on their surface, on the interface between the recording layer and the cover layer, or on the interface between the recording layer and the substrate. In these cases, plane waves incident upon the optical recording medium were refracted and scattered at the respective positions to form various holograms as shown by way of example in FIG. 6. This was found to cause the variation of the reflected beam depending on the location of the recording medium.

Accordingly, alteration recording by focusing a laser beam on such a reflection hologram, which has a significant variation in the reflected beam, does not allow for distinguishing oscillations of the hologram itself from the variation resulting from the alteration recording. This would thus make recording and reading on the optical recording medium substantially difficult to implement.

### SUMMARY OF THE INVENTION

In view of the foregoing problems, various exemplary embodiments of this invention provide a method for forming reflection holograms on an information recording layer of an optical recording medium in order to implement a reflection hologram recording medium having uniform reflectivity.

In summary, the above-described objectives are achieved by the following embodiments of the present invention.

(1) A method for forming a reflection hologram on an information recording layer of an optical recording medium, the method comprising: focusing a first laser beam through an objective lens, the first beam satisfying a condition given by, 4λn/(NA)²<D, where λ (μm) is a wavelength, NA is a numerical aperture of the objective lens, n is an average refractive index of the optical recording medium, and D (μm) is a thickness of the medium; allowing the first laser beam to interfere with a second laser beam within the optical recording medium, the second laser beam opposing the first beam and satisfying the same condition as that of the first beam; and allowing the optical recording medium and a flux of the laser beams to be displaced relative to each other, thereby forming a reflection hologram.

(2) The hologram formation method according to (1), wherein the laser beam is designed to satisfy a condition given by d/2≦4λn/(NA)², where d (μm) is a thickness of the information recording layer.

According to the hologram formation method of the present invention, a focused laser beam is used to form a reflection hologram and implement a reflection hologram recording medium having uniform reflectivity. It is thus possible to realize good recording and reading operations and high-density recording.

### BRIEF DESCRIPTION OF THE DRAWINGS

FIG. 1 is a block diagram schematically illustrating a reflection hologram recording optical system for forming a format signal using a hologram formation method according to an embodiment of the present invention;

FIG. 2 is a block diagram schematically illustrating a reflection hologram reading optical system for reading a format signal formed using a hologram formation method according to an embodiment of the present invention;

FIG. 3 is a cross-sectional view schematically illustrating an optical recording medium and a laser beam for forming a reflection hologram using a hologram formation method according to an embodiment of the present invention;

FIG. 4 is a schematic view illustrating a laser beam for forming a reflection hologram using a hologram formation method according to an embodiment of the present invention;

FIG. 5 is a block diagram schematically illustrating a reflection hologram alteration recording optical system for alteration recording using a hologram formation method according to an embodiment of the present invention;

FIG. 6 is a schematic view illustrating a laser beam for forming a reflection hologram using a hologram formation method according to a comparative example;

FIG. 7 is a block diagram schematically illustrating a reflection hologram recording optical system for forming a format signal using a hologram formation method according to a comparative example;

FIG. 8 is a block diagram schematically illustrating a reflection hologram reading optical system for reading a format signal formed using a hologram formation method according to a comparative example; and

FIG. 9 is a cross-sectional view schematically illustrating an optical recording medium and a laser beam, different from those of FIG. 3, for forming a reflection hologram using a hologram formation method according to an embodiment of the present invention.

### DETAILED DESCRIPTION OF THE PREFERRED EMBODIMENTS

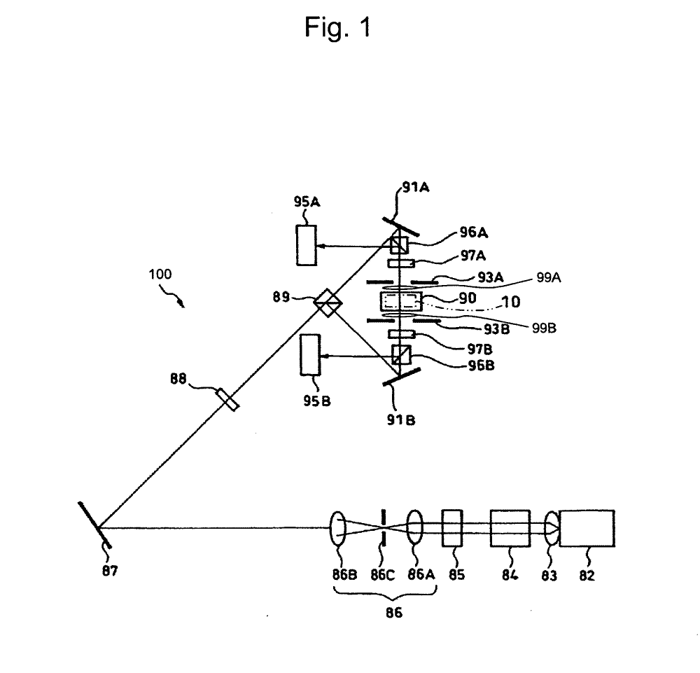

With reference to FIG. 1, a description will be made to a reflection hologram recording optical system 100, which is useful for forming uniform reflection holograms, according to an embodiment of the present invention.

As shown in FIG. 1, an external cavity LD (hereinafter, referred to as “ECLD”) 82 emits a laser beam, elliptical in cross section, at a wavelength of 405 nm. The beam passes through an anamorphic prism 83 and is shaped to be generally circular and then passes through an isolator 84. The isolator 84 prevents a reflected beam from coming back into the ECLD 82 to thereby make lasing unstable.

The laser beam that passed through the isolator 84 is provided with an improved beam profile through a spatial filter 86 having a combination of a shutter 85, a pair of lenses 86A and 86B, and a pin hole 86C. The beam is also expanded in its beam diameter, and thus turned into a collimated beam of approximately 10φ in diameter.

The collimated beam is reflected on a mirror 87 and thereafter, polarized to be a p-polarization beam through a half-wave plate (hereinafter, referred to as “HWP”) 88. The p-polarization beam is split into two light beams through a beam splitter (hereinafter, referred to as “BS”) 89.

The two p-polarization beams are reflected on mirrors 91A and 91B, then passed through polarizing beam splitters (hereinafter, referred to as “PBS”) 96A and 96B, and circularly polarized through ¼ wavelength plates (hereinafter, referred to as “QWP”) 97A and 97B, respectively. The beams are then reduced into a beam of about 4φ in diameter through apertures 93A and 93B, focused by objective lenses 99A and 99B, and adjusted to focus in the optical recording medium 10 set up in a sample holder 90, respectively. The two circularly polarized beams are adapted to interfere with each other in the optical recording medium 10, thereby forming a reflection hologram.

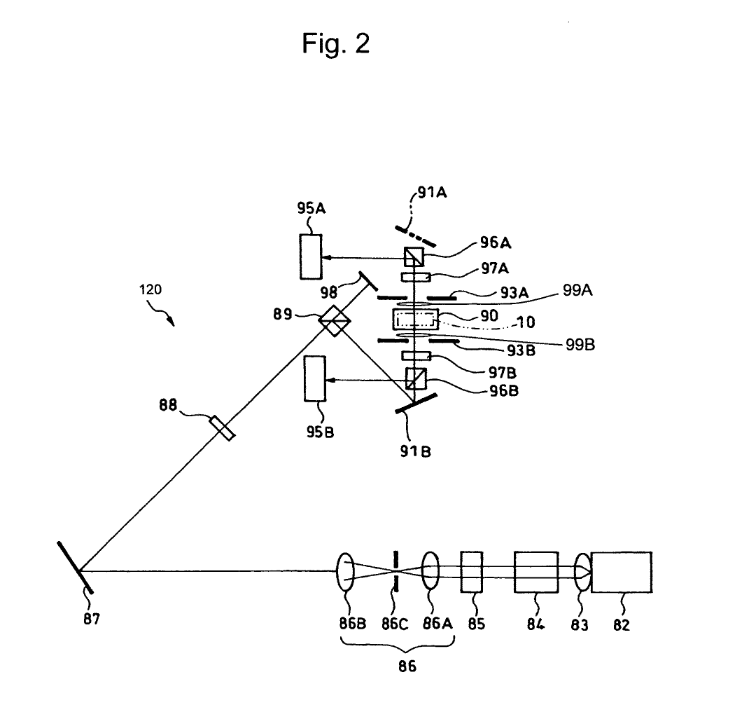

To read the reflection hologram, use is made of a reflection hologram reading optical system 120 shown in FIG. 2. This optical system is different from the reflection hologram recording optical system 100 of FIG. 1 in additionally having a shield plate 98 for blocking one of the two beams into which the p-polarization was split through the BS 89. Thus, the optical system 120 is adapted to use only one light beam. The other components are the same as those of the optical system 100, so that those same components will be denoted with the same reference symbols as those of FIG. 1 without any further explanations.

The p-polarization beam that passed through the BS 89 is reflected on the mirror 91B, passed through the PBS 96B, circularly polarized through the QWP 97B, reduced to about 4φ in beam diameter through the aperture 93B, and then focused through the objective lens 99B into the optical recording medium 10 set up in the sample holder 90. The focused circular polarization beam is diffracted by the reflection hologram in the optical recording medium 10, and thus split into a transmitted beam and a reflected beam.

The transmitted beam is collimated through the objective lens 99A, passed through the aperture 93A, polarized to be an s-polarization beam through the QWP 97A, and reflected on the PBS 96A to be directed into a detector 95A.

Likewise, the reflected beam is also collimated through the objective lens 99B, passed through the aperture 93B, polarized to be an s-polarization beam through the QWP97B, and then reflected on the PBS 96B to be directed into a detector 95B.

It is possible to determine the diffraction efficiency of the formed reflection hologram by calculating the strength of the reflected beam to the total amount of the transmitted beam and the reflected beam.

The optical recording medium 10 includes a substrate 32, an information recording layer 34, and a cover layer 36, which are deposited in that order. The recording layer 34 has a thickness equal to the stack of a first recording area 34A (next to the substrate 32) and a second recording area 34B (next to the cover layer 36), which are equal in thickness in the direction of depth of the optical recording medium 10. The layer 34 is continuously formed in the direction of the thickness. Note that in practice, there is no interface between the first and second recording area 34A and 34B.

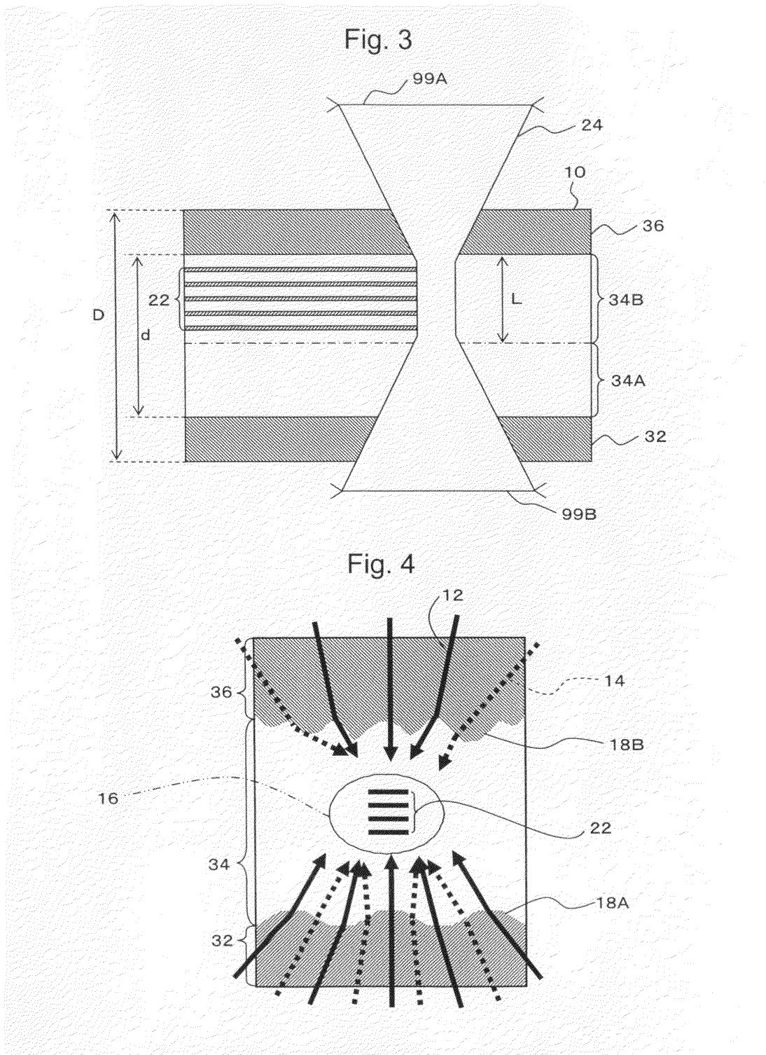

Referring to FIG. 3, a first laser beam focused through the objective lens 99A and an opposing second laser beam focused through the objective lens 99B are allowed to interfere with each other within the optical recording medium 10 to provide a flux of the laser beams 24. Here, the first and second laser beams satisfy the same certain condition to be described later. The flux 24 and the optical recording medium 10 are displaced relative to each other to form a resulting interference pattern (reflection hologram) 22 in the second recording area 34B. The alternate long and short dashed line of FIG. 3 indicates the halfway line of the recording film (the information recording layer 34) in the direction of depth, D is the total thickness of the optical recording medium 10, d is the thickness of the recording film, and L is the depth of the focused region.

In FIGS. 4 and 6, those laser beams for forming reflection holograms are compared with each other according to the availability of the objective lens for focusing operations. The solid arrows in the figure denote a coherent beam 12, the broken arrows show a non-coherent beam 14, and the ellipse at the center shows a hologram formation region 16.

FIG. 4 shows a laser beam used when forming a reflection hologram in the information recording layer 34 by focusing through the objective lens (here, one of the first and second information recording layers 34A and 34B is shown as the information recording layer 34). In contrast to this, FIG. 6 shows how a reflection hologram is formed through the mutual interference of plane waves without the objective lens. In this case, the undulations 18A and 18B on the interface cause the optical axis of incident beams to be bent and those opposing laser beams to form their respective interference patterns 22. Thus, no uniform holograms are formed within the optical recording medium 10.

An undulation of any interface can affect the resulting interference pattern so long as the opposing incident beams pass through that interface before forming the hologram. That is, the gradient of the undulation would cause the incident beams to be refracted even if the spot diameter of the laser beam is reduced to be less than the cycle of the undulation. Thus, the resulting interference pattern is to be affected.

The interface that has a particularly serious effect is the one between media that have a big refractive index difference. Accordingly, the undulations of the surfaces of the substrate and the cover layer, which are the interfaces of the recording medium in contact with air, have a great effect.

When forming a reflection hologram using light beams focused through an objective lens, any beam having an optical path bent due to the undulation of an interface cannot be focused. Accordingly, a reflection hologram that is formed by focused opposing beams is a uniform hologram.

In this case, the focused plane wave region has to be narrower than the thickness from the surface of the substrate to the surface of the cover layer. A plane wave region being wider than the thickness from the surface of the substrate to the surface of the cover layer allows a plane wave to be incident upon the interface between the recording medium and air. This would be the same as the formation of interference patterns between plane waves, thereby disabling the formation of uniform holograms.

The depth L (μm) of the plane wave interference region (focused region) and the width w (μm) of the focused region are determined by the wavelength λ (μm), the numerical aperture NA of the objective lenses, and the average refractive index n of the optical recording medium, as shown in the equations below.

L=4λn/NA² (1)

w=λ/NA (2)

Accordingly, the thickness from the surface of the substrate to the surface of the cover layer, i.e., the total thickness of the optical recording medium, D (μm), has to be greater than the depth L of the focused region, i.e., has to meet the equation below.

L=4λn/(NA)²<D (3)

Here, the average refractive index of the optical recording medium means the average refractive index of the focused region. For example, with the focused region including a substrate 1, a recording film, and a substrate 2, the medium average refractive index n can be expressed by the following equation;

N=(nₛ₁dₛ₁+nᵣdᵣ+nₛ₂dₛ₂)/(dₛ₁+dᵣ+dₛ₂) (4)

where nₛ₁, nᵣ, and nₛ₂ are their respective refractive indices, and dₛ₁, dᵣ, and dₛ₂ are their respective thicknesses.

It is most preferable to form the format collectively in the direction of depth of the optical recording medium. However, in sequentially forming them in a plurality of recording areas, they are preferably formed in a less number of recording areas. This is because an increase in the number of recording areas would increase the number of steps of forming reflection holograms at additional costs. Furthermore, in forming interference patterns through polymerization of photopolymers, such regions with no holograms formed would also be exposed to light and cause polymerization reactions to take place, thus forming holograms with less efficiency. Accordingly, letting d (μm) being the thickness of the recording film, the number of recording areas are preferably divided into two or more, preferably satisfying the equation below.

d/2≦L=4λn/(NA)² (5)

In FIG. 3, it holds that d/2=L=4λn/(NA)².

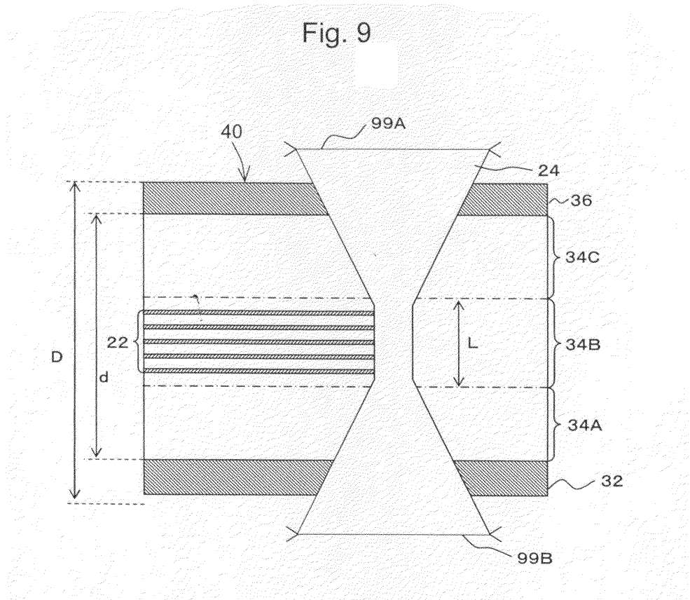

Note that an increase in the number of recording areas may not much increase the costs or exposing the regions with no hologram formed to light may also not degrade the efficiency of forming holograms. In these cases, the recording area may be divided into three or more like an optical recording medium 40 as shown in FIG. 9.

In FIG. 9, a symbol 34C indicates the third recording area. The other components that are the same as those of the optical recording medium 10 shown in FIG. 3 are indicated with the same symbols without further explanations.

### First Embodiment

The disc-shaped optical recording medium 10 with a hologram formed was manufactured as follows.

### (Manufacturing of Medium)

7.3 g of tetrabutoxy titanium (Ti(OBu)₄, manufactured by Kojundo Chemical Laboratory Co., Ltd.) and 5.04 g of 2-ethylpentane-2,4-diol (manufactured by Tokyo Chemical Industry Co., Ltd.) were mixed in 2 ml of an n-buthanol solvent at room temperature and stirred for ten minutes. At that time, the mole ratio was Ti(OBu)₄:2-methylpentane-2,4-diol=1:2.

This reaction solution was mixed with 5.2 g of diphenyldimethoxysilane (PH₂Si(OMe)₂ manufactured by Shin-Etsu Chemical Co., Ltd.) into a metal alkoxide solution. At that time, the mole ratio was Ti:Si=1:1.

Next, a solution made up of 0.4 ml of water, 0.16 ml of 2N hydrochloric acid, and 2 ml of solvent ethanol was added dropwise at room temperature into the metal alkoxide solution while being stirred. The stirring continued for 30 minutes to cause hydrolysis reaction and condensation reaction, thereby forming a solated solution.

Three weight parts of IRG-907 (manufactured by Ciba Specialty Chemicals) as a photopolymerization initiator and 0.3 weight parts of 2,4-diethyl-QH-thioxan-9-on as a photosensitizer were added to 100 weight parts of polyethylene glycol monoacrylate (manufactured by Kyoeisha Chemical Co., Ltd.:130A) as a photopolymerizable compound to form a mixture that contains a photopolymerizable compound.

To contain 75 weight parts of the matrix material as a nonvolatile component and 25 weight parts of the photopolymerizable compound, i.e., the matrix material: the photopolymerizable compound=4:1, a mixture of a solated solution and a photopolymerizable compound were mixed at room temperature. While being blocked from light, the mixture was allowed to go through the sol-gel reaction for another one hour, thereby providing a hologram recording material solution.

While being blocked from light, the resulting solution was heated and condensed at 80° C. to obtain a solution for application use. While still being blocked from light, the application solution was applied onto a glass substrate by means of a spin coater, which was then dried in an oven for 20 hours at 80° C. An optical recording medium having a recording film thickness of 20 μm was thus obtained. This optical recording medium was applied with a UV curable resin by spin coating. The film was so adjusted as to be 87.5 μm in thickness from the surface to the recording layer.

The resulting optical recording medium 10 was formatted using the reflection hologram recording optical system 100 shown in FIG. 1.

The objective lenses 99A and 99B for focusing in the optical recording medium 10 were a plano-convex lens of 0.1 in terms of NA. The plane wave interference region was estimated as below from Equations (1) and (2), λ=0.405 μm (405 nm), NA=0.1, and the refractive index of the optical recording medium 10 being n=1.62;

Width w=4 μμm, and

Depth L=260 μm.

The optical recording medium 10 was mounted on a rotation stage, and while being rotated, one cycle of reflection hologram was formed.

The optical recording medium 10 with the reflection hologram formed was set to the sample holder 90 of the reflection hologram reading optical system 120 shown in FIG. 2 to reproduce the reflection hologram. A uniform reflectivity of 20% was observed. It was thus found that the optical recording medium 10 was successfully formatted.

### (Reading on Microscopic Hologram Region)

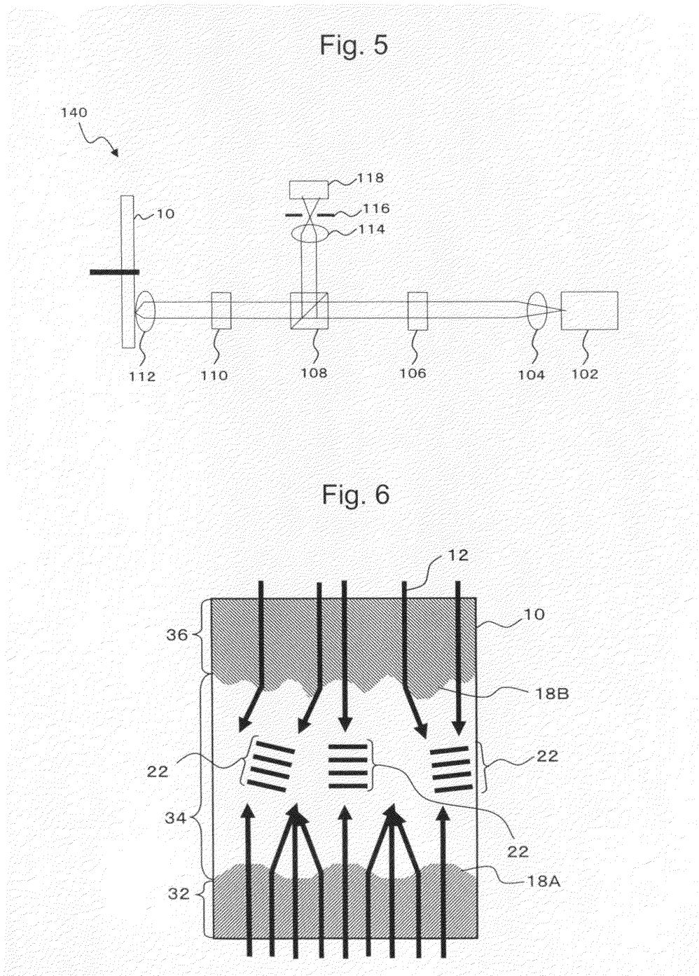

To read on a microscopic region of the reflection hologram, the optical system was built as shown in FIG. 5. The spread beams emitted from a blue laser (PLD) 102 of a wavelength 0.405 μm were collimated through a collimator lens (CL) 104, and then polarized to a p-polarization through a HWP 106. The p-polarization passed through a PBS 108, circularly polarized at a QWP 110, and then focused in the optical recording medium 10 by an objective lens 112.

The focused, circularly polarized, converged beam was collimated near the focal point, so that the collimated beam interferes with the reflection hologram formed in the optical recording medium 10 to generate a reflected beam (diffracted beam).

The reflected beam passed again through the QWP 110, polarized to an s-polarization, reflected on a PBS 108 at a right angle, focused through a lens 114, passed through a pin hole 116, and then detected at a detector 118.

The plane wave interference region of the built optical system can be estimated as below from λ=0.405 μm (405 nm), NA=0.85, and the refractive index of the medium being n=1.62;

Width w=0.48 μm, and

Depth L=3.6 μm.

The reflected beam from the reflection hologram of this region was detected.

The pin hole 116 provided immediately in front of the detector 118 is intended to block other stray light than the reflected beam from the reflection hologram.

The optical recording medium 10 with the reflection hologram formed thereon was located in the optical system mentioned above, and then irradiated with a blue laser while it is at standstill. The objective lens 112 used had reduced spherical aberration at the position 87.5 μm from the surface of the optical recording medium 10. The recording was performed at a depth of 87.5 μm in the recording layer from the surface of the optical recording medium 10.

When a microscopic region of the hologram was read using a reflection hologram alteration recording optical system 140 of FIG. 5, a good reflected signal with reduced variation in reflectivity was obtained. That is, it was found that the optical recording medium 10 is a reflection type hologram recording medium which has uniform reflectivity.

### First Comparative Example

### Formation of Reflection Hologram

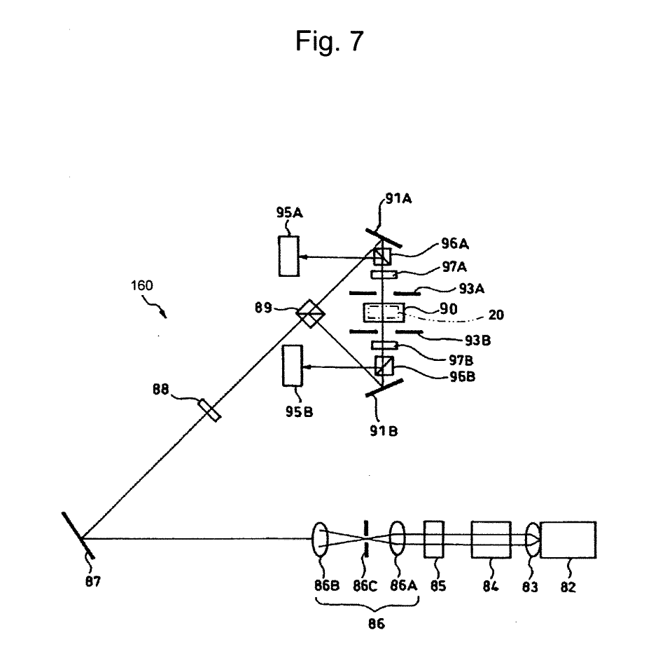

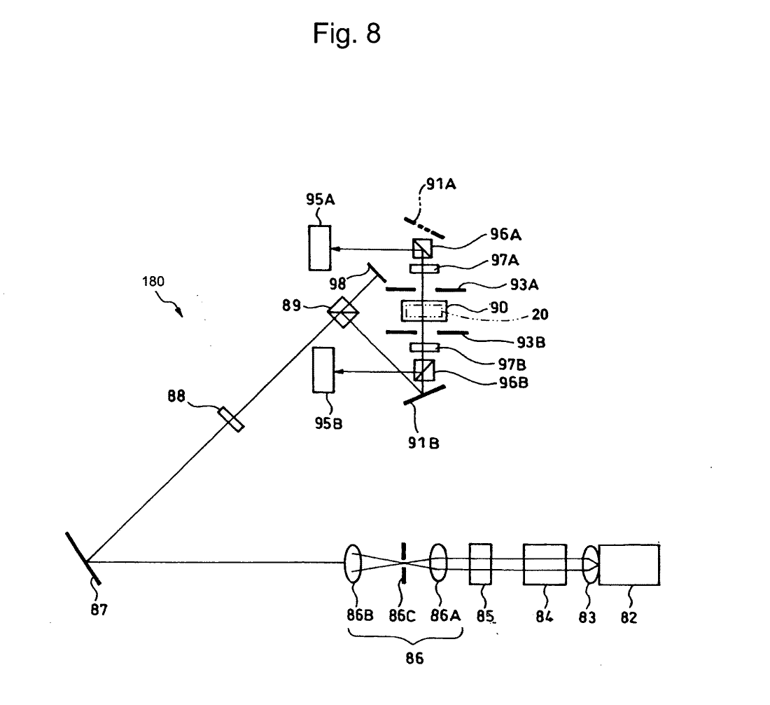

As with the first embodiment, a disc-shaped optical recording medium 20 was fabricated, so that the optical recording medium 20 was provided with a reflection hologram as follows. To form the reflection hologram, the optical system shown in FIGS. 7 and 8 was constructed.

The reflection hologram was formed by a reflection hologram recording optical system 160 shown in FIG. 7. This optical system 160 is equivalent to the reflection hologram recording optical system 100 shown in FIG. 1 with the objective lenses 99A and 99B being eliminated. The other components are the same as those of the reflection hologram recording optical system 100, and thus indicated with the same symbols as those of FIG. 1 with no further explanation. The optical paths to the apertures 93A and 93B are the same as those of the reflection hologram recording optical system 100.

The two p-polarized beams are condensed to a beam of approximately 4φ in diameter through the apertures 93A and 93B, respectively, and then incident upon the optical recording medium 20 from the opposite directions and interfere with each other

The optical recording medium 20 was set to the sample holder 90, so that the two p-polarized beams interfere with each other to form a reflection hologram.

The write laser power of each of the beams was 600 μW and the medium 20 was exposed thereto for 60 seconds. Thereafter, using an LED of a center wavelength of 0.400 μm (400 nm), the recording material was post cured to complete the polymerization reaction.

### (Reading of Reflection Hologram)

Holograms were read using a reflection hologram reading optical system 180 shown in FIG. 8. The optical system 180 is equivalent to the reflection hologram reading optical system 120 shown in FIG. 2 from which the objective lenses 99A and 99B are eliminated. The other components are the same as those of the reflection hologram reading optical system 120, and thus indicated with the same symbols as those of FIG. 2 with no further explanation. The optical paths to the apertures 93A and 93B are the same as those of the reflection hologram reading optical system 120.

The circularly polarized beams are condensed to a beam of approximately 4φ in diameter through the apertures 93A and 93B, and then directed to the optical recording medium 20 with a reflection hologram formed therein, allowing the medium 20 to be irradiated therewith. The irradiation beam is directed into the optical recording medium 20 in the normal direction, and separated into the reflected beam and the transmitted beam by the reflection hologram. Both the reflected beam and the transmitted beam pass through the QWP 97B and 97A again, thereby being polarized to an s-polarization. The s-polarization beam is all reflected on the PBS 96B and 96A in the direction of right angles. The reflected beam and the transmitted beam are detected by the photodetectors 95B and 95A to find their intensity, respectively. The ratio of the reflected beam to the sum of the reflected beam and the transmitted beam is calculated, thereby determining the reflectivity (diffraction efficiency) of the reflection hologram formed.

The optical recording medium 20, on which data had been recorded, was set to the sample holder of the optical system shown in FIG. 8 to read the reflection hologram. Through this reading operation, observed was a 20% uniform reflectivity. It was thus found that the optical recording medium 20 was successfully formatted.

Next, the optical recording medium 20 was rotated to observe variations in reflectivity around the position of irradiation. The observation provided great variations in reflectivity, which had a cycle of a few μm to a few tens of μm. That is, the optical recording medium 20 was found to be a reflection type hologram recording medium with great variations in the reflected beam depending on the position of detection.

Note that in the embodiments, the information recording layer of the optical recording medium 10 was virtually divided into two in the direction of depth allowing each to form an interference pattern. However, the present invention is not limited to the number of divisions of the information recording layer. For example, as shown in FIG. 9, the information recording layer of an optical recording medium 40 may be virtually divided into three recording areas 34A, 34B and 34C. The present invention is also applicable to an optical recording medium with its information recording layer being not virtually divided as well as to an optical recording medium having a plurality of information recording layers.

What is claimed is:

1. A method for forming a reflection hologram on an information recording layer of an optical recording medium, the method comprising:
focusing a first laser beam through an objective lens, the first beam satisfying a condition given by,
4λn/(NA)²<D,
where λ (μm) is a wavelength, NA is a numerical aperture of the objective lens, n is an average refractive index of the optical recording medium, and D (μm) is a thickness of the medium;
allowing the first laser beam to interfere with a second laser beam within the optical recording medium, the second laser beam opposing the first beam and satisfying the same condition as that of the first beam; and
allowing the optical recording medium and a flux of the laser beams to be displaced relative to each other, thereby forming a reflection hologram.

2. The hologram formation method according to claim 1, wherein the laser beam is designed to satisfy a condition given by
d/2≦4λn/(NA)²,
where d (μm) is a thickness of the information recording layer.
